(19) United States
(12) Patent Application Publication
(10) Pub. No.: US 2023/0229208 A1
(43) Pub. Date: Jul. 20, 2023

(54) AIR-LIQUID COMPOSITE COOLER FOR MEMORY MODULE

(71) Applicant: Taiwan Microloops Corp., New Taipei City (TW)

(72) Inventors: Chun-Hung Lin, New Taipei City (TW); Hamid Nalbandian, New Taipei City (TW); Chun-Teng Chiu, New Taipei City (TW); Kuang-Lu Lee, New Taipei City (TW)

(21) Appl. No.: 17/840,456

(22) Filed: Jun. 14, 2022

(30) Foreign Application Priority Data
Jan. 14, 2022 (TW) 111101738

(51) Int. Cl. G06F 1/20; H05K 7/20

(52) U.S. Cl. CPC G06F 1/20; H05K 7/20336; G06F 2200/201

(57) ABSTRACT

An air-liquid composite cooler for a memory module is provided. The memory module has a top portion and two side portions. The air-liquid composite cooler includes a liquid-cooling structure and a pair of air-cooling structures. The liquid-cooling structure is arranged on the top portion and has a liquid passage. The air-cooling structure is arranged on a side portion, and includes a phase-change thermo-conductive member. One end of the phase-change thermo-conductive member contacts the liquid-cooling structure to conduct heat and another end of the phase-change thermo-conductive member is extended in a direction away from the liquid-cooling structure. Therefore, the overall cooling efficiency of the cooler may be improved.

### BACKGROUND

### Technical Field

The disclosure relates to a cooler, particularly to an air-liquid composite cooler for a memory module.

### Related Art

With the increase of speed of data process of computers, waste heat from chips of a memory module also rises. The waste heat is being accumulated in the computer case and causes temperature increase in working environment and poor performance to chips in the memory module, and may further damages chips and makes computers crash if it is not effectively removed.

A related-art cooler for a memory module is to attach a cooling plate with fins and a fan on a chip of the memory, and a fan of the computer case is used to eject waste heat out of the computer case for cooling. However, because the waste heat blown by the fan is nondirectional, the waste heat is accumulated in the computer case first and then ejected by the fan of the computer case, so that the cooling efficiency is poor.

In view of this, the inventors have devoted themselves to the above-mentioned related art, researched intensively and cooperated with the application of science to try to solve the above-mentioned problems. Finally, the disclosure which is reasonable and effective to overcome the above drawbacks is provided.

### SUMMARY

An object of the disclosure is to provide an air-liquid composite cooler for a memory module, which uses rapid thermo-conduction of a phase-change thermo-conductive member and a high cooling property of a liquid-cooling structure to improve overall cooling efficiency of the cooler.

To accomplish the above object, the disclosure provides an air-liquid composite cooler for a memory module. The memory module has a top portion and two side portions. The air-liquid composite cooler includes a liquid-cooling structure and a pair of air-cooling structures. The liquid-cooling structure is arranged on the top portion and has a liquid passage. The pair of air-cooling structures is separately arranged on the two side portions. Each air-cooling structure includes a phase-change thermo-conductive member. One end of the phase-change thermo-conductive member contacts the liquid-cooling structure to conduct heat and another end of the phase-change thermo-conductive member is extended in a direction away from the liquid-cooling structure.

The disclosure further has the following functions. By the liquid-cooling structure, the waste heat generated by each chip may be directionally guided out and dissipated. By the parallelly connected tubes and each cooling plate extended from each tube, the effects of components capable of being jointly used and easily being combined may be achieved.

### BRIEF DESCRIPTION OF THE DRAWINGS

FIG. 1 is an exploded view of the first embodiment of the disclosure;

FIG. 2 is an exploded view of the first embodiment of the disclosure applied to a memory module;

FIG. 3 is an assembled schematic view of the first embodiment of the disclosure applied to a memory module;

FIG. 4 is a cross-sectional view of the first embodiment of the disclosure applied to a memory module;

FIG. 5 is an exploded view of the second embodiment of the disclosure;

FIG. 6 is a cross-sectional view of the second embodiment of the disclosure applied to a memory module;

FIG. 7 is an assembled view of the third embodiment of the disclosure;

FIG. 8 is a cross-sectional view of the third embodiment of the disclosure applied to a memory module;

FIG. 9 is a cross-sectional view of the fourth embodiment of the disclosure applied to a memory module;

FIG. 10 is an exploded view of the fifth embodiment of the disclosure; and

FIG. 11 is a cross-sectional view of the fifth embodiment of the disclosure applied to a memory module.

### DETAILED DESCRIPTION

The technical contents of this disclosure will become apparent with the detailed description of embodiments accompanied with the illustration of related drawings as follows. It is intended that the embodiments and drawings disclosed herein are to be considered illustrative rather than restrictive.

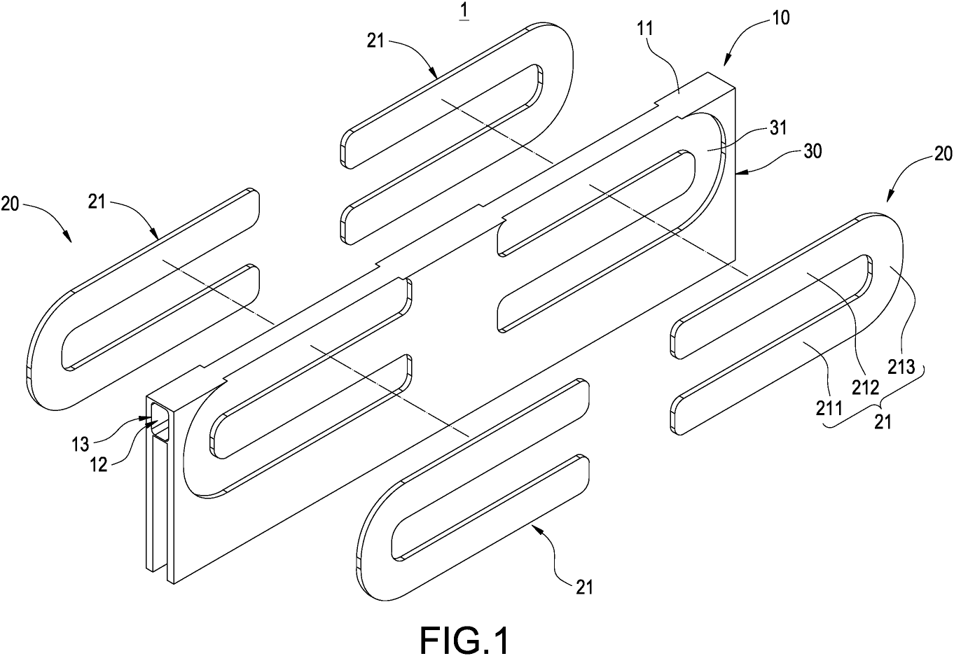

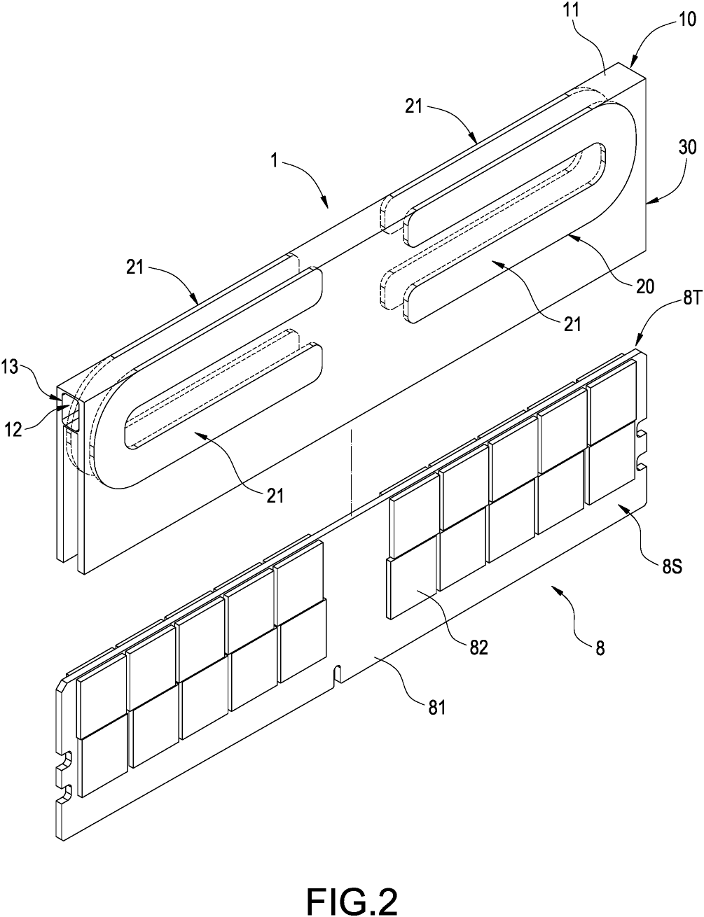

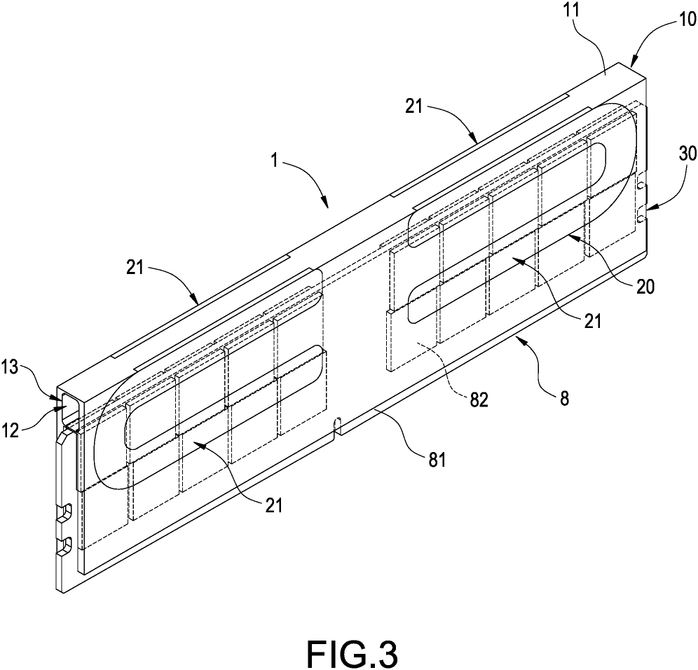

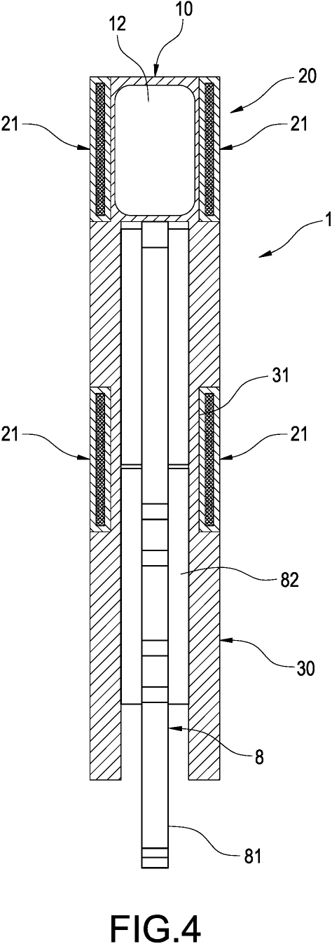

Please refer to FIGS. 1-4. The disclosure provides an air-liquid composite cooler for a memory module. The memory module 8 includes a circuit board 81 and multiple memories (memory units) 82. The memories 82 are arranged on two sides of the circuit board 81 at intervals. An upper area of the circuit board 81 constitutes a top portion 8T of the memory module 8. An area of the circuit board 81 facing a rear area of each memory 82 constitutes a side portion 8S of the memory module 8. The air-liquid composite cooler 1 includes a liquid-cooling structure 10 and a pair of air-cooling structures 20.

The liquid-cooling structure 10 is arranged on the top portion 8T. The liquid-cooling structure 10 of the embodiment includes a tube 11 of an elongated shape. A liquid passage 12 is formed in the tube 11. Each of two ends of the tube 11 has an opening 13. Each opening 13 may be connected with a connector (not shown in figures) and a liquid-cooling device (not shown in figures) is used to convey liquid and make heat exchange to the liquid passage 12.

Each air-cooling structure 20 is separately arranged on the two side portions 8S. Each air-cooling structure 20 includes a phase-change thermo-conductive member 21. In the embodiment, the number of the phase-change thermo-conductive member 21 is, but not limited to, four. The phase-change thermo-conductive member 21 may be a plate heat pipe or a vapor chamber, which has a vacuum chamber, a wick structure and a working fluid disposed inside to make heat transfer by gas-liquid phase change.

In an embodiment, the phase-change thermo-conductive member 21 is of a U-shape. The phase-change thermo-conductive member 21 has an evaporation section 211, a condensation section 212 and a heat insulation section 213 disposed between the condensation section 212 and the evaporation section 211.

The air-liquid composite cooler 1 of the disclosure further includes a pair of cooling plates 30. The cooling plates 30 are extended from two sides of the tube 11 toward the same direction. Outer sides of the tube 11 and each cooling plate 30 are separately formed with multiple troughs 31. The shape of each trough 31 matches the shape of the phase-change thermo-conductive member 21 for embedding the phase-change thermo-conductive member 21. The condensation section 212 contacts the liquid-cooling structure 10 to conduct heat. The evaporation section 211 is attached on the cooling plate 30 and extended in a direction away from the liquid-cooling structure 10. The cooling plate 30 may be made of metal with desirable thermo-conductivity, such as aluminum, copper, or an alloy thereof.

When using, an inner side of each cooling plate 30 is attached on a surface of each memory 82. The heat generated by each memory 82 during operation is transferred to each cooling plate 30 first, then passes the evaporation section 211, the heat insulation section 213 and the condensation section 212 of the phase-change thermo-conductive member 21, and is dissipated by the liquid in the liquid passage 12 via the thermal connection between the condensation section 212 and the tube 11. After the heat exchanges between the condensation section 212 and the liquid-cooling structure 10, the working fluid in the condensation section 212 is condensed into liquid working fluid. The liquid working fluid may rapidly flow back to the evaporation section 211 by the capillary suction of the wick structure to complete a circular cooling process.

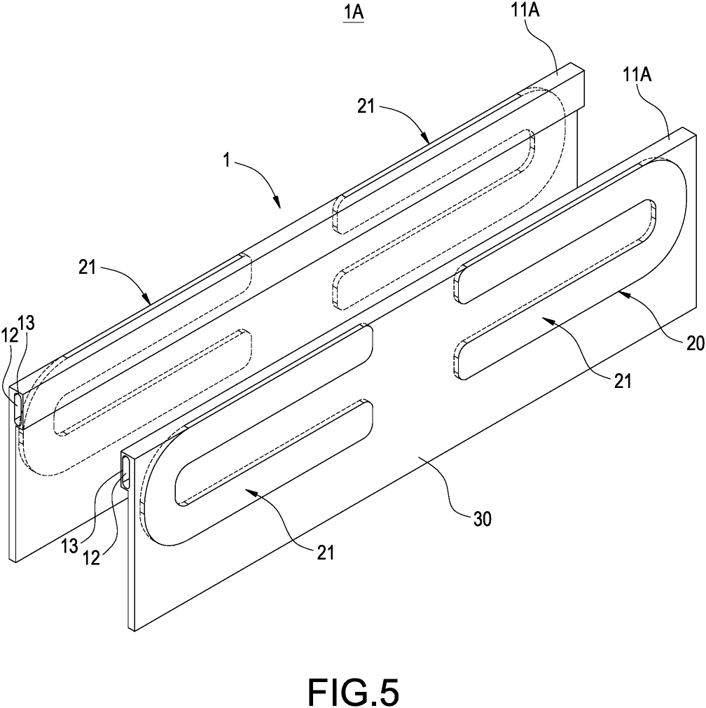

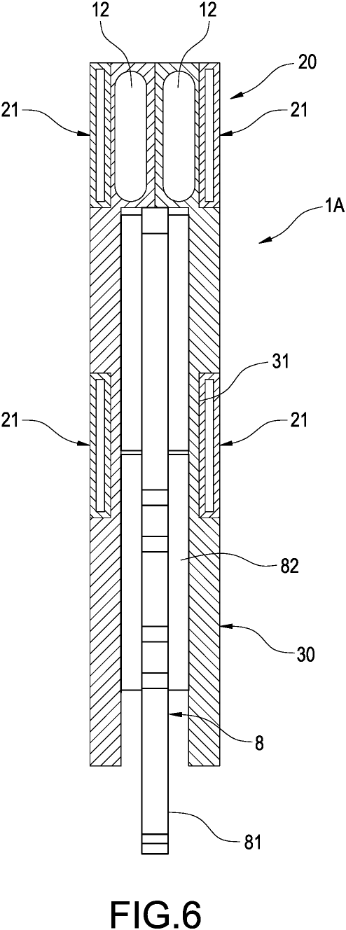

Please refer to FIGS. 5 and 6. The differences between the air-liquid composite cooler 1A of the present embodiment and the abovementioned air-liquid composite cooler 1 are that the liquid-cooling structure 10 of the cooler 1A includes two tubes 11A, each tube 11A has a liquid passage 12 and two openings 13. A lateral side of each tube 11A is downward extended with a cooling plate 30. The tubes 11A are connected in a side-by-side manner. Each phase-change thermo-conductive member 21 is embedded in the sides of the tube 11A and the cooling plate 30. As a result, the effect of components being jointly used and easily being combined may be achieved.

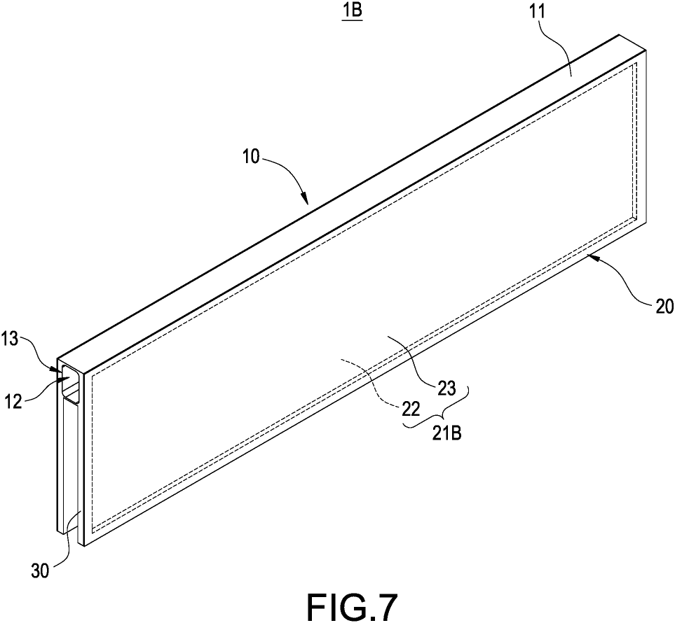

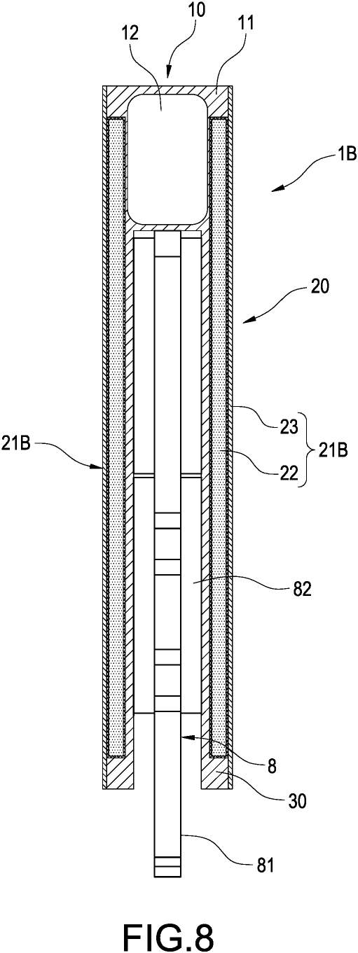

Please refer to FIGS. 7 and 8. The differences between the air-liquid composite cooler 1B of the present embodiment and the abovementioned air-liquid composite cooler 1, 1A are that the phase-change thermo-conductive member 21B of the embodiment is directly formed with a chamber 22 in the cooling plate 30, a wick structure is placed in the chamber 22, and the chamber 22 is covered and sealed by a cover 23. After that, the phase-change thermo-conductive member 21B may be obtained by the processes of filling working fluid, degassing, and sealing. In other words, the phase-change thermo-conductive member 21B is directly formed on each cooling plate 30 and the cooling plate 30 serves as the bottom and the annular frame of the phase-change thermo-conductive member 21B.

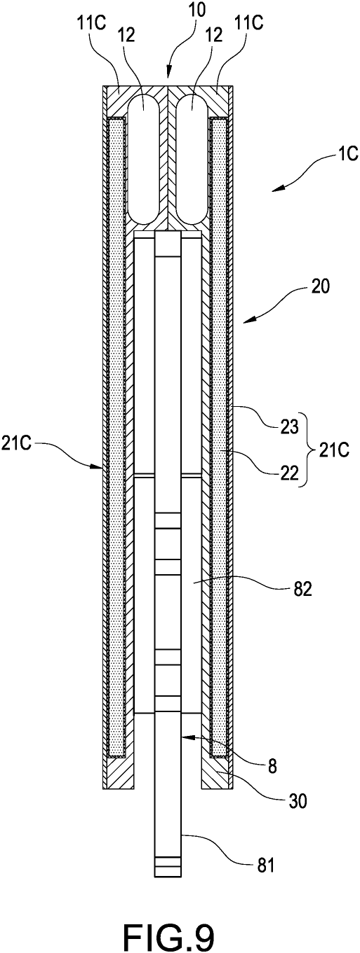

Please refer to FIG. 9. The differences between the air-liquid composite cooler 1C of the present embodiment and the abovementioned air-liquid composite cooler 1B are that the liquid-cooling structure 10 of the cooler 1C includes two tubes 11C, and a lateral side of each tube 11C is downward extended with a cooling plate 30. The phase-change thermo-conductive member 21C of the embodiment is directly formed with a chamber 22 in the cooling plate 30, a wick structure is placed in the chamber 22, and the chamber 22 is covered and sealed by a cover 23. After that, the phase-change thermo-conductive member 21C may be obtained by the processes of filling working fluid, degassing, and sealing. Also, the tubes 11C are connected in a side-by-side manner to configure the cooler 1C. As a result, the effect of components being jointly used and easily being combined may be achieved.

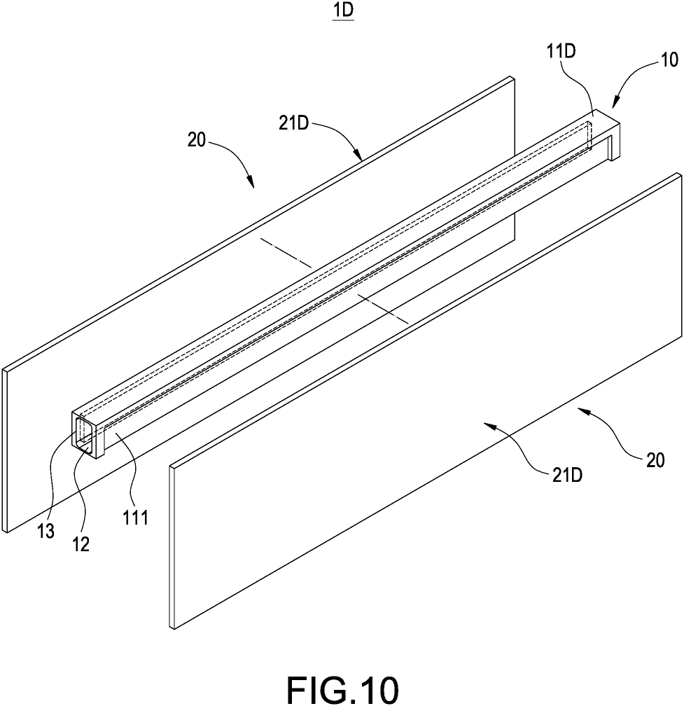

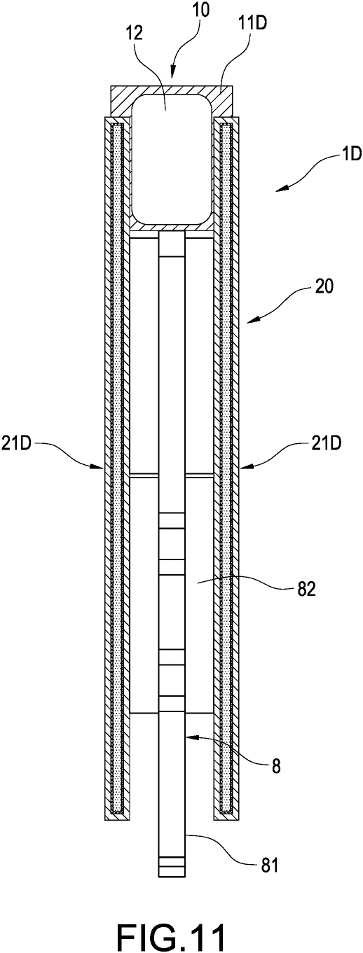

Please refer to FIGS. 10 and 11. The differences between the air-liquid composite cooler 1D of the present embodiment and the abovementioned air-liquid composite cooler 1C are that the liquid-cooling structure 10 includes a tube 11D, and each of two sides of the tube 11D is formed with a trench 111. The tube 11D also has a liquid passage 12 and two openings 13. Each phase-change thermo-conductive member 21D is a rectangular plate and is embedded in each trench 111 correspondingly.

While this disclosure has been described by means of specific embodiments, numerous modifications and variations could be made thereto by those skilled in the art without departing from the scope and spirit of this disclosure set forth in the claims.

What is claimed is:

1. An air-liquid composite cooler for a memory module, the memory module comprising a top portion and two side portions, the air-liquid composite cooler comprising:
a liquid-cooling structure, arranged on the top portion, and comprising a liquid passage; and
a pair of air-cooling structures, separately arranged on the two side portions, each air-cooling structure comprising a phase-change thermo-conductive member, one end of the phase-change thermo-conductive member contacting the liquid-cooling structure to conduct heat, and another end of the phase-change thermo-conductive member extended in a direction away from the liquid-cooling structure.

2. The air-liquid composite cooler of claim 1, wherein the liquid-cooling structure comprises a tube of an elongated shape, the liquid passage is disposed in the tube, and the tube comprises an opening defined on two ends thereof respectively.

3. The air-liquid composite cooler of claim 2, further comprising a pair of cooling plates, wherein each cooling plate is extended from two sides of the tube toward a same direction, multiple troughs are separately defined on the tube and each cooling plate, and each phase-change thermo-conductive member is embedded in each trough.

4. The air-liquid composite cooler of claim 3, wherein the phase-change thermo-conductive member is of a U-shape and comprises an evaporation section, a condensation section and a heat insulation section between the condensation section and the evaporation section, the condensation section contacts the tube to conduct heat, and the evaporation section is attached on the cooling plate and extended in a direction away from the liquid-cooling structure.

5. The air-liquid composite cooler of claim 1, wherein the phase-change thermo-conductive member is a plate heat pipe or a vapor chamber.

6. The air-liquid composite cooler of claim 1, wherein the liquid-cooling structure comprises a plurality of tubes, each tube comprises the liquid passage, and the tubes are connected parallelly.

7. The air-liquid composite cooler of claim 6, wherein each tube comprises a cooling plate extended on a lateral side thereof, and each phase-change thermo-conductive member is embedded in each tube and each cooling plate.

8. The air-liquid composite cooler of claim 1, further comprising: a pair of cooling plates, wherein the liquid-cooling structure comprises a tube, the liquid passage is disposed in the tube, and the cooling plates are extended from two sides of the tube toward a same direction.

9. The air-liquid composite cooler of claim 8, further comprising: a pair of covers, wherein each cooling plate comprises a chamber, a wick structure and a working fluid are disposed in the chamber, and each phase-change thermo-conductive member is configured through each cover covering the chamber of each cooling plate.

10. The air-liquid composite cooler of claim 1, further comprising: a pair of covers, wherein the liquid-cooling structure comprises two tubes, each tube comprises the liquid passage, the tubes are connected parallelly, and each cooling plate is extended from a lateral side of each tube toward a same direction.

11. The air-liquid composite cooler of claim 10, further comprising: a pair of covers, wherein each cooling plate comprises a chamber, a wick structure and a working fluid are disposed in the chamber, and each phase-change thermo-conductive member is configured through each cover covering the chamber of each cooling plate.

12. The air-liquid composite cooler of claim 1, wherein the liquid-cooling structure comprises a tube, the liquid passage is disposed in the tube, a trench is respectively disposed on two sides of the tube, and each phase-change thermo-conductive member is a rectangular plate and embedded in each trench correspondingly.
